(19) United States
(12) Patent Application Publication
(10) Pub. No.: US 2022/0129865 A1
(43) Pub. Date: Apr. 28, 2022

(54) METHOD FOR MONITORING AN ELECTRICAL DEVICE

(71) Applicant: Siemens Energy Global GmbH & Co. KG, Muenchen (DE)

(72) Inventors: Christoph Armschat, Erlangen (DE); Markus Distler, Effeltrich (DE); Joerg Hafermaas, Erlangen (DE); Nicolas Soellner, Erlangen (DE); Uwe Weigt, Erlangen (DE); Anna Soergel, Nuernberg (DE)

(21) Appl. No.: 17/599,016

(22) PCT Filed: Mar. 28, 2019
(86) PCT No.: PCT/EP2019/057823

§ 371 Date: Sep. 28, 2021

(51) Int. Cl. G06Q 10/00; G01R 31/40; G05B 23/02; H02J 13/00; H02J 3/00

(52) U.S. Cl. CPC G06Q 10/20; G01R 31/40; H02J 3/0012; H02J 13/00002; G05B 23/0235

(57) ABSTRACT

A method for monitoring an electrical device connected to an electrical transmission network includes providing measured operating state data of a first electrical device, providing measured operating state data of further electrical devices of the same type as the first electrical device being connected to the transmission network, comparing the operating state data or at least one variable derived therefrom with at least one predetermined data pattern, the operating state data of the first and all further electrical devices being included in the comparison, and providing information about control measures and/or maintenance measures that are to be carried out and are assigned to the data pattern, if the result of the comparison is a match with the data pattern. A data processing device for performing the method is also provided.

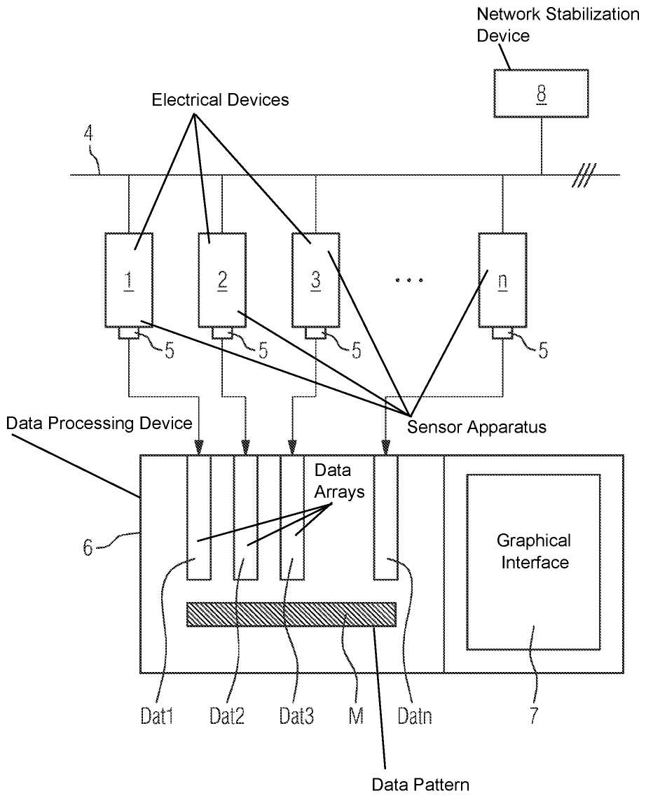

The invention relates to a method for monitoring an electrical device which is connected to an electrical transmission network.

The electrical transmission network may be, for example, a high-voltage or medium-voltage supply network which is operated with an AC voltage. The electrical device may be accordingly suitably designed for an operating voltage at the high-voltage or medium-voltage level above 1 kV. If the electrical device is connected to the electrical transmission network, it may also be understood as being a part of this transmission network.

The electrical device may be, for example, a surge arrester, switchgear (for example a circuit breaker), a transformer (high-voltage transformer) with a tap changer or the like. Failure of one of the devices mentioned may result in a breakdown of an entire energy transmission system or an entire subnetwork. Therefore, there is generally a great need for reliable monitoring of such devices.

The object of the invention is to specify a method mentioned at the outset which makes it possible to monitor electrical devices as effectively and reliably as possible.

The object is achieved, according to the invention, by means of a method for monitoring a first electrical device which is connected to a transmission network, having the following method steps of: providing measured operating state data relating to the first electrical device, providing measured operating state data relating to further electrical devices which are similar to the first electrical device and are connected to the transmission network, comparing the operating state data or at least one variable derived therefrom with at least one predetermined data pattern, wherein the comparison is carried out with the inclusion of the operating state data relating to the first and all further electrical devices, providing an item of information relating to control and/or maintenance measures, which are to be carried out and are assigned to the data pattern, if the comparison reveals a correspondence to the data pattern. The operating state data can be expediently provided by storing them in a storage medium of a data processing device. In this case, the operating state data are captured by means of suitable sensors of the electrical devices and are transmitted for provision. In this case, the sensors may already be installed in the devices or may be arranged as external apparatuses on the devices or in the spatial vicinity of the latter. The transmission is preferably effected by radio, in any case advantageously, but not necessarily, wirelessly. The data processing device or its memory may also be present in a cloud, for example in a manner distributed among a plurality of apparatuses. The electrical devices are similar to one another, that is to say they are electrical devices with an identical or similar function and a basic structure. Examples are circuit breakers of the same type, transformers, surge arresters, high-voltage bushings, capacitor units and the like. The operating state data are compared with the data pattern, in which case it is likewise possible to examine the derived variables, for example differences between the operating state data, their changes over time or statistical variables obtained from the operating state data. The data pattern(s) is/are predetermined and expediently stored. The data pattern(s) may be or comprise threshold values, predetermined data sequences, value relationships between data such as correlations, statistical hypotheses. In this case, a plurality of partial patterns may define a data pattern. According to the invention, the comparison is carried out with the inclusion of the provided data not only relating to the first device but also relating to the other electrical devices. That is to say, the first electrical device is monitored on the basis of measurement data from a plurality of similar devices. The provision of the information relating to the control measures and/or maintenance measures is the result of the analysis and can, but need not, result in the immediate performance of the proposed control or maintenance measures. A control measure is, for example, a transfer of the first electrical device to another operating state or operating point. A maintenance measure is, for example, a replacement or cleaning of components. The measures to be carried out can be carried out in an automated manner or manually by maintenance personnel. It goes without saying that it is possible to monitor not only the first electrical device but also the other devices with the aid of the analysis of the operating state data.

One advantage of the method according to the invention is the possibility of monitoring the electrical device in a relatively seamless and at the same time cost-effective manner. The pattern recognition also makes it advantageously possible to identify clusters of particular events and to take suitable control and/or maintenance measures in good time. An example in this context is a cluster of surge arrester responses in connection with the switching of lines, as a result of the growth of trees and disruption by birds or in connection with flashovers to ground or phase-to-phase flashovers, which results in overloading or premature ageing of the apparatuses. A further example is the detection of an increased number of switching operations of tap changers on transformers, for example in connection with certain network configurations. Another example is the detection of an increased creepage current on insulator surfaces (for example on the binding layer of an inductor) and partial discharges to insulators. In particular, in comparison with independent parallel monitoring of individual devices, the monitoring of an electrical device on the basis of data relating to a plurality of similar electrical devices has the crucial advantage that slow parameter changes or individual events which affect all devices can be identified as such and can be taken into account. Overall, depending on the application, the method according to the invention makes it possible to advantageously reduce switching operations at the tap changer of a transformer, numbers of responses of surge arresters in the case of switching overvoltages, voltage spikes on insulators and mechanical loads caused by current surges or higher-frequency currents (for example harmonic currents with a multiple of the network frequency, in particular in the case of inductors).

The data pattern suitably comprises a temporal correlation between a predetermined operating state of the first electrical device and a predetermined network state of the transmission network. This means that a correspondence of the operating state data to the data pattern presupposes that the operating state data have the described correlation. For example, opposed correction mechanisms of voltage dividers at transformers of different voltage levels may be detected. Furthermore, an increased response of surge arresters which coincides with certain network configurations and/or switching operations in the transmission network can be detected in this manner. In this case, remedial action can be achieved in the form of a modification of the network configuration, a pre-definition of switching operations which take place in a temporally staggered manner in the transmission network or by retrofitting switch synchronization apparatuses or compensation apparatuses or vibration damping apparatuses.

The information expediently comprises a control measure, according to which reactive power is exchanged between a network stabilization device connected to the transmission network and the transmission network in a manner coordinated in terms of time with the at least one predetermined operating state of the first electrical device. Reactive power can be exchanged in a coordinated manner, for example, by changing the reactive power flow in the transmission network, which may be caused by changing a reactive power contribution by an HVDC system (high-voltage direct current transmission system), a FACTS system or by simply connecting or disconnecting shunt reactors or shunt capacitors. If, for example, a switching operation in the transmission network, which normally causes a switching overvoltage or a switching undervoltage, is carried out in a manner coordinated in terms of time with the corrective reactive power change, the effect of the switching operation can be considerably reduced. Overall, the stability of the transmission network is advantageously increased in this manner.

In order to reduce the volumes of data, the operating state data are preferably provided in a compressed form. In a simple case, threshold value information can be transmitted and provided instead of analog values (for example in the form: “current is greater than the threshold value of X amps” or “voltage is greater than 130% of the nominal voltage”).

Furthermore, the operating state data provided may be subjected to a delay correction. In the worst case, the operating state data are provided with a certain time delay, wherein the delay generally depends on the location of the electrical device and can therefore vary for the operating state data relating to two different devices. The delay correction advantageously allows this delay to be eliminated. In the simplest case, the correction can be achieved with the aid of time stamping of the operating state data.

According to one embodiment of the invention, the first electrical device is a transformer, wherein the operating state data comprise switching operations at tap changers of the transformers.

According to a further embodiment of the invention, the first electrical device is a surge arrester, wherein the operating state data comprise measured internal leakage currents and the data pattern comprises an asymmetry of the internal leakage currents. An imminent overload or failure of individual devices of the electrical devices can be identified by examining the leakage currents and the asymmetry. The electrical devices may be arranged in an arrester bank, for example.

The operating state data may also comprise measured external leakage currents (these leakage currents correspond to so-called contamination layer currents, creepage currents caused by contamination). In this case, the data pattern may comprise an increase in a leakage current. In this case, an external leakage current is understood as meaning a creepage current over an external surface of an insulator. The increase in the leakage currents is an indicator of local contamination of insulators which is severe under certain circumstances. Undesirable flashovers to the insulators can be avoided by examining the external leakage currents. In this case, insulators may be components of surge arresters, post insulators or bushings and other system parts.

According to a further embodiment of the invention, the first electrical device is a switching device, wherein the operating state data comprise a temporal assignment of switching operations of the switching device. The temporal assignment, for example a time stamp, easily allows an examination of the correlation of the switching operations with a voltage profile in the transmission network.

It is also conceivable to record or store a mechanical fingerprint of the electrical device (wherein the fingerprint is suitably a characteristic of the acceleration over time). Such an individual fingerprint can be compared with a characteristic fingerprint of an entire fleet of electrical devices (for example similar switching devices, motor pumping units, air-conditioning system compressors, oil pumps, fans and cooler motors). According to one example in which the electrical device is a switching device, an acceleration sensor can always be arranged in the same position and orientation in a drive box in the case of similar switching devices. Recording of a snapshot (acceleration profile over the entire running time of the drive) is initiated as soon as a switching command is transmitted to a drive unit of the switching device. Characteristic peaks in the recorded acceleration profile are analyzed and evaluated with respect to their number, amplitude and temporal sequence. This makes it possible to identify an emerging sluggishness of the mechanics of the switching device or, for example, a drive part which has been worn or damaged from any anomalies in the acceleration profile.

The invention also relates to a data processing device.

The object of the invention is to propose a data processing device which makes it possible to reliably monitor the electrical device.

The object is achieved, according to the invention, by means of a data processing device which is configured to carry out a method according to the invention.

The advantages of the data processing device according to the invention emerge, in particular, from the advantages which have already been described in connection with the method according to the invention.

The invention is explained further below on the basis of an exemplary embodiment illustrated in the FIGURE.

The FIGURE shows a schematic illustration of an exemplary embodiment of the method according to the invention.

Accordingly, the FIGURE illustrates a first electrical device 1, for example switchgear. The first electrical device 1 is connected to a three-phase transmission or supply network 4. At the same time, some further electrical devices 2-n which have a similar structure to the first electrical device 1 and are likewise connected to the supply network 4 are illustrated. The first and further electrical devices 1-n each have their own sensor apparatus 5 which captures operating state data relating to the assigned device 1-n and transmits said data to a data processing device 6.

The operating state data relating to the first and further electrical devices 1-n which are provided in this manner are stored in the form of data arrays Dat1-Datn in a memory of the data processing device 6. The stored data can then be processed and analyzed.

The possibly processed operating state data, that is to say accordingly derived variables, are compared with a predetermined data pattern M. In this case, the data pattern M generally need not comprise a sequence of stipulated values, but rather may also comprise, for example, specifications of dependencies between the individual stored operating state data Dat1-n or deviations from an average behavior of the operating state data. The comparison is therefore effected with the inclusion of the operating state data relating to the first and all further electrical devices.

If it is identified that the specifications of the data pattern are complied with, an item of information relating to control and/or maintenance measures which are to be carried out and are assigned to the data pattern is provided. In the example illustrated, the provision is effected by means of a graphical interface 7.

In this case, the information provided comprises a proposed control measure, according to which reactive power is to be exchanged between a network stabilization device 8 connected to the transmission network 4 and the transmission network 4 in a manner coordinated in terms of time with a predetermined operating state of the first electrical device 1. In the example illustrated in the FIGURE, the predetermined operating state of the first electrical device 1 is a switching operation which is carried out by means of the first electrical device. The negative effects of the switching operation on the supply network 4 can be reduced by exchanging the reactive power in a temporally coordinated manner.

A measure which includes an exchange of active power is likewise conceivable, wherein the active power can be exchanged by means of a pulse load resistor or a pulse generator.

1-10 (canceled)

11. A method for monitoring a first electrical device connected to an electrical transmission network, the method comprising:
providing measured operating state data relating to the first electrical device;
providing measured operating state data relating to further electrical devices being similar to the first electrical device and being connected to the transmission network;
comparing the operating state data or at least one variable derived from the operating state data with at least one predetermined data pattern, and carrying out the comparison with an inclusion of the operating state data relating to the first electrical device and all further electrical devices; and
providing an item of information relating to at least one of control or maintenance measures to be carried out and assigned to the data pattern, upon a correspondence to the data pattern revealed by the comparison.

12. The method according to claim 11, which further comprises including a temporal correlation between a predetermined operating state of the first electrical device and a predetermined network state of the transmission network in the data pattern.

13. The method according to claim 12, which further comprises including in the information a control measure exchanging reactive power between a network stabilization device connected to the transmission network and the transmission network in a manner coordinated in terms of time with at least one predetermined operating state of the first electrical device.

14. The method according to claim 11, which further comprises providing the operating state data in a compressed form.

15. The method according to claim 11, which further comprises subjecting the provided operating state data to a delay correction.

16. The method according to claim 11, which further comprises providing a transformer as the first electrical device, and including switching operations at a tap changer of the transformer in the operating state data.

17. The method according to claim 11, which further comprises providing a surge arrester as the first electrical device, including measured internal leakage currents in the operating state data, and including an asymmetry of the internal leakage currents in the data pattern.

18. The method according to claim 17, which further comprises including measured external leakage currents in the operating state data, and including an increase in a leakage current in the data pattern.

19. The method according to claim 11, which further comprises providing a switching device as the first electrical device, and including a temporal assignment of switching operations of the switching device in the operating state data.

20. A data processing device configured to carry out the method according to claim 11.
